(19) United States
(12) Patent Application Publication
(10) Pub. No.: US 2026/0068684 A1
(43) Pub. Date: Mar. 5, 2026

(54) ANTENNA PACKAGE STRUCTURE AND METHOD OF FORMING THE SAME

(71) Applicant: MEDIATEK INC., Hsinchu City (TW)

(72) Inventors: Ya-Jui HSIEH, Hsinchu City (TW); Chi-Yuan CHEN, Hsinchu City (TW); Sang-Mao CHIU, Hsinchu City (TW); Kai-Cheng WANG, Hsinchu City (TW); Shih-Chin LIN, Hsinchu City (TW)

(21) Appl. No.: 18/967,759

(22) Filed: Dec. 4, 2024

Related U.S. Application Data
(60) Provisional application No. 63/689,022, filed on Aug. 30, 2024.

(51) Int. Cl. H01L 23/66; H01L 21/48; H01L 21/56; H01L 23/498; H01L 23/552; H01L 25/16

(52) U.S. Cl. CPC H01L 23/66

(57) ABSTRACT

An antenna package structure includes a substrate, a communication device, and a shielding layer. The substrate has an upper portion and a lower portion. The lower portion includes an antenna layer. The substrate has stepped sidewalls on opposite sides, and each of the stepped sidewalls includes a sidewall of the upper portion and a sidewall of the lower portion. The communication device is attached to the upper portion of the substrate. The shielding layer covers the communication device and the sidewall of the upper portion of the substrate.

### CROSS REFERENCE TO RELATED APPLICATIONS

This application claims the benefit of U.S. Provisional Application No. 63/689,022 filed on Aug. 30, 2024, the entirety of which is incorporated by reference herein.

### BACKGROUND OF THE INVENTION

### Field of the Invention

The present invention relates to semiconductor technology, and, in particular, to an antenna package structure.

### Description of the Related Art

Wireless communication devices are increasingly popular and increasingly complex. These wireless communication devices typically include antennas to support communication over a range of frequencies. In order to integrate one or more antennas with other electronic circuits in the same package, antenna-in-package (AiP) technology is often used. The AiP technology that implements an antenna integrated into a semiconductor package structure can balance antenna performance, cost and reduction of the device size. For example, integrating an antenna and a radio frequency integrated circuit (RFIC) in the same unit can boost the signal and reduce the transfer losses.

Although existing antenna package structures generally meet requirements, they have not been satisfactory in all respects. Integrating the antenna and the RFIC in the same unit also brings some challenges. For example, the antenna needs to radiate and receive electromagnetic waves; however, the RFIC should be isolated to prevent electromagnetic waves. This results in contradiction. Therefore, further improvements in antenna package structures are required.

### BRIEF SUMMARY OF THE INVENTION

Antenna package structures are provided. An exemplary embodiment of an antenna package structure includes a substrate, a communication device, and a shielding layer. The substrate has an upper portion and a lower portion. The lower portion includes an antenna layer. The substrate has stepped sidewalls on opposite sides, and each of the stepped sidewalls includes a sidewall of the upper portion and a sidewall of the lower portion. The communication device is mounted onto the upper portion of the substrate. The shielding layer covers the communication device and the sidewall of the upper portion of the substrate.

Another embodiment of an antenna package structure includes a substrate, a communication device, a molding material, a conductive connector, and a shielding layer. The substrate includes an antenna layer and a module layer disposed over the antenna layer. A sidewall of the module layer protrudes relative to a sidewall of the antenna layer. The communication device is disposed over the module layer of the substrate. The molding material encapsulates the communication device. The conductive connector is adjacent to the molding material. The shielding layer extends on sidewalls of the molding material and the sidewall of the module layer.

Methods for forming an antenna package structure are also provided. An exemplary embodiment of a method for forming an antenna package structure includes attaching a communication device to a first side of a substrate. The substrate includes an antenna layer on a second side of the substrate. The method for forming the antenna package structure also includes forming a first opening in the substrate. The method for forming the antenna package structure also includes forming a shielding layer over the communication device and in the first opening. The method for forming the antenna package structure also includes forming a second opening in the substrate to the first opening to cut through the substrate.

### BRIEF DESCRIPTION OF THE DRAWINGS

The present invention can be more fully understood by reading the subsequent detailed description and examples with references made to the accompanying drawings, wherein:

FIGS. 1A to 1G are cross-sectional views of various stages of manufacturing an exemplary antenna package structure in accordance with some embodiments of the present disclosure;

FIG. 2 is a bottom view of a substrate of an exemplary antenna package structure in accordance with some embodiments of the present disclosure;

FIG. 3 is a cross-sectional view of an exemplary antenna package structure in accordance with some embodiments of the present disclosure; and

FIG. 4 is a cross-sectional view of an exemplary antenna package structure in accordance with some embodiments of the present disclosure.

### DETAILED DESCRIPTION OF THE INVENTION

The following description is made for the purpose of illustrating the general principles of the invention and should not be taken in a limiting sense. The scope of the invention is best determined by reference to the appended claims.

The present disclosure will be described with respect to particular embodiments and with reference to certain drawings, but the disclosure is not limited thereto and is only limited by the claims. The drawings described are only schematic and are non-limiting. In the drawings, the size of some of the elements may be exaggerated for illustrative purposes and not drawn to scale. The dimensions and the relative dimensions do not correspond to actual dimensions in the practice of the disclosure.

Additional elements may be added on the basis of the embodiments described below. For example, the description of “a first element on/over a second element” may include embodiments in which the first element is in direct contact with the second element, and may also include embodiments in which additional elements are disposed between the first element and the second element such that the first element and the second element are not in direct contact.

Furthermore, the description of “a first element extending through a second element” may include embodiments in which the first element is disposed in the second element and extends from a side of the second element to an opposite side of the second element, wherein a surface of the first element may be substantially leveled with a surface of the second element, or a surface of the first element may be outside a surface of the second element.

The spatially relative descriptors of the first element and the second element may change as the structure is operated or used in different orientations. In addition, the present disclosure may repeat reference numerals and/or letters in the various embodiments. This repetition is for simplicity and clarity and does not in itself dictate a relationship between the various embodiments discussed.

An antenna package structure and a method for forming the antenna package structure are described in accordance with some embodiments of the present disclosure. The antenna package structure includes an antenna layer and a communication device, wherein the communication device is covered by a shielding layer while the antenna layer is exposed. As a result, the antenna can work normally without adversely affecting the operation of the communication device.

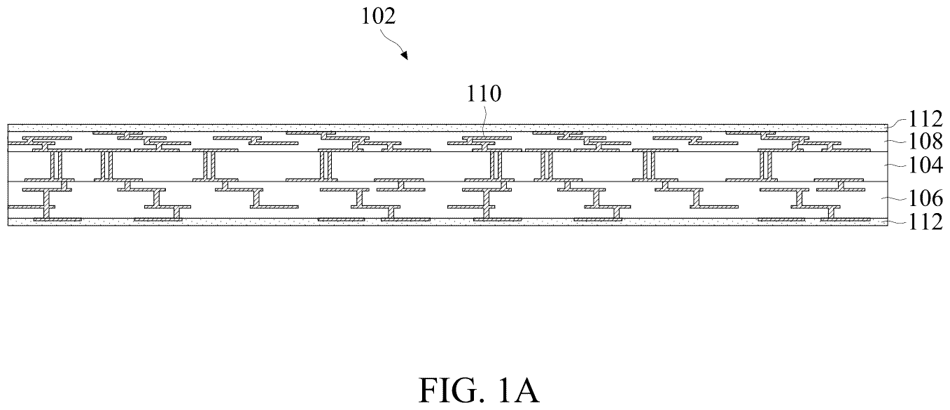

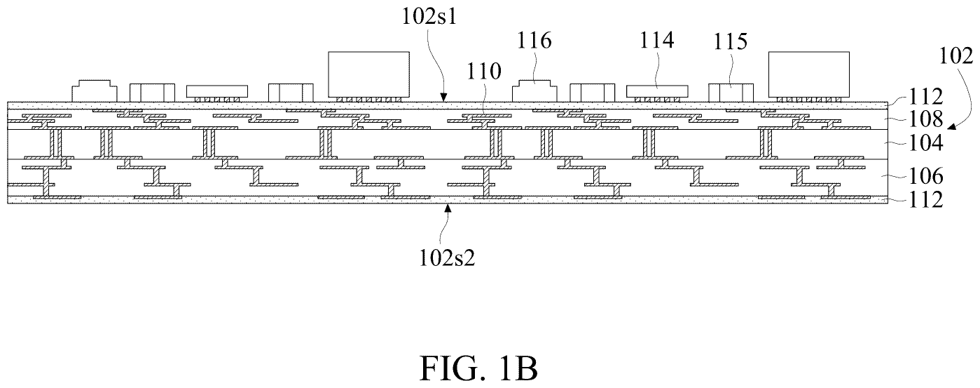

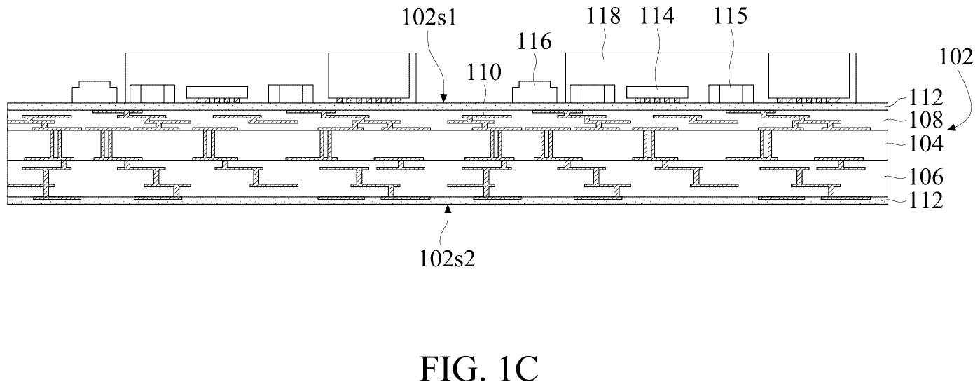

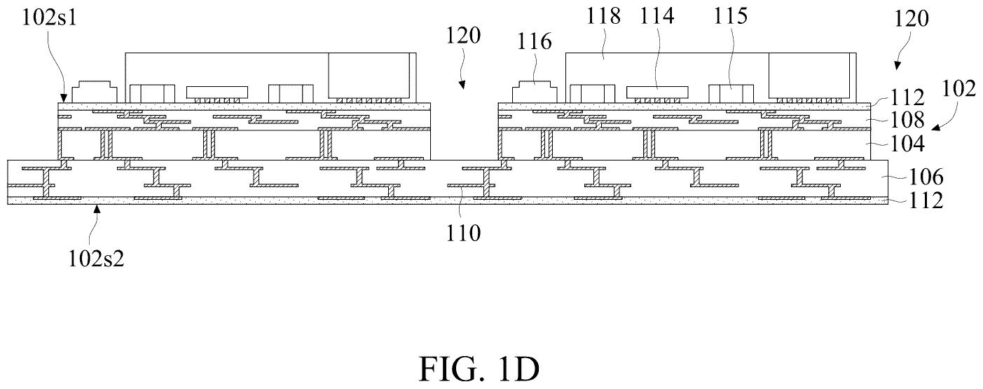

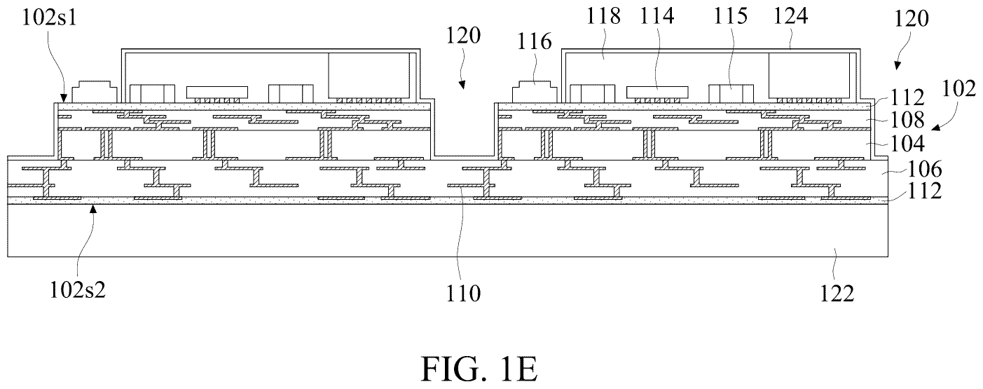

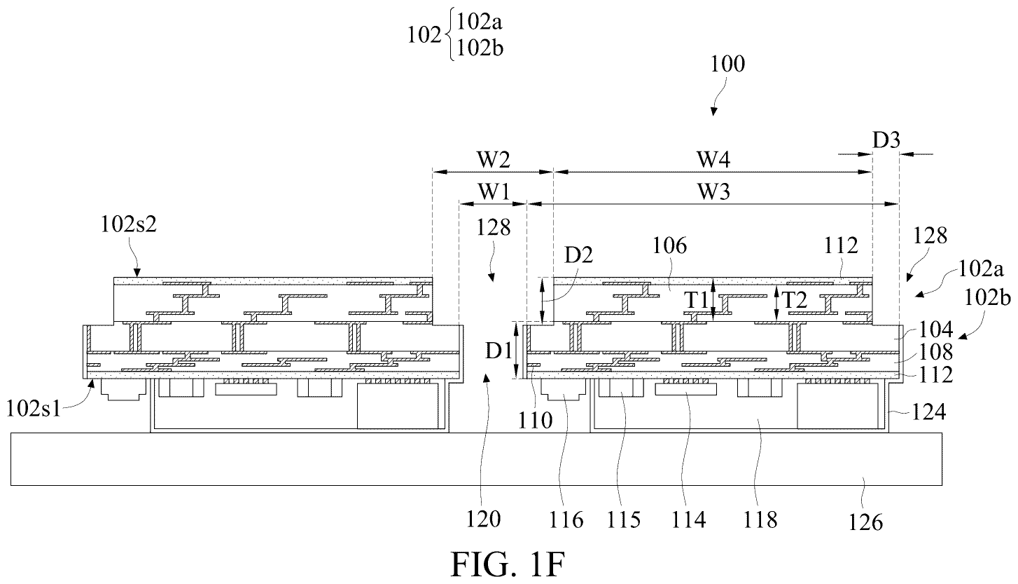

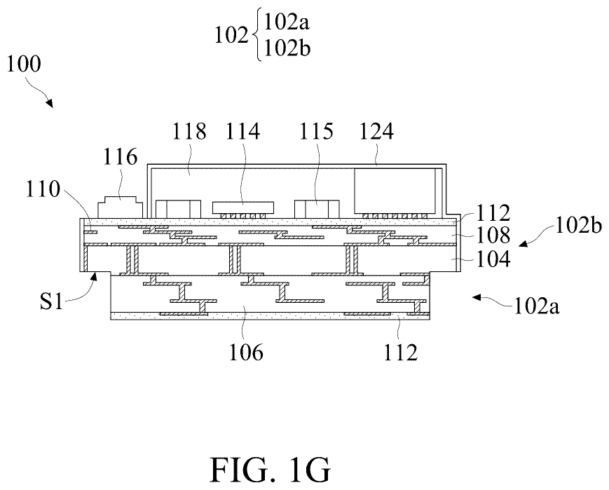

FIGS. 1A to 1G are cross-sectional views of various stages of manufacturing an antenna package structure 100 in accordance with some embodiments of the present disclosure. Additional features can be added to the antenna package structure 100. Some of the features described below can be replaced or eliminated for different embodiments. To simplify the diagram, only a portion of the antenna package structure 100 is illustrated.

As illustrated in FIG. 1A, a substrate 102 is provided, in accordance with some embodiments. The substrate 102 may be a package substrate or any suitable substrate. The substrate 102 may have a core structure 104. The core structure 104 may be formed of an organic material, a glass material, a ceramic material, a semiconductor material, the like, or a combination thereof. The organic material may include fiberglass resin (e.g., FR4), bismaleimide triazine (BT) resin, the like, or a combination thereof. The semiconductor material may include silicon, germanium, or a compound material, including silicon germanium, silicon carbide, gallium arsenic, silicon germanium carbide, the like, or a combination thereof. One or more through vias may be formed through the core structure 104.

The substrate 102 has an antenna layer 106 and a module layer 108 on opposite sides of the core structure 104, in accordance with some embodiments. The antenna layer 106 and the module layer 108 may each include routing layers 110 disposed in dielectric layers. The dielectric layers may be formed of polymer, including polyimide (PI), polybenzoxazole (PBO), benzocyclobutene (BCB), epoxy, ceramic, the like, or a combination thereof. Alternatively, the dielectric layers may be formed of silicon oxide, silicon nitride, silicon oxynitride, the like, or a combination thereof.

The routing layers 110 may include horizontal interconnects, such as conductive layers or conductive pads, and vertical interconnects, such as conductive vias. The conductive vias may electrically couple different levels of the conductive layers and the conductive pads. The routing layers 110 may be formed of metal, including tungsten, titanium, tantalum, ruthenium, cobalt, copper, aluminum, platinum, tin, silver, gold, the like, an alloy thereof, or a combination thereof.

The routing layers 110 in the antenna layer 106 may include radiators, feeding lines, another suitable components, or a combination thereof. The routing layers 110 in the module layer 108 may include power lines, grounding lines, signal lines, another suitable components, or a combination thereof.

Protective layers 112 are disposed over the module layer 108 and below the antenna layer 106 to protect the exposed surfaces of the antenna layer 106 and the module layer 108, in accordance with some embodiments. The protective layers 112 may include a solder resist layer. The protective layers 112 may be formed of a resin material (such as a thermosetting resin, a photosensitive resin, or the like), an ink material, a tape material (such as polyimide tape, kapton tape, or the like), the like, or a combination thereof. The protective layers 112 may be formed by printing, coating, or another suitable methods.

The substrate 102 may have a first surface 102s1 and a second surface 102s2 opposite the first surface 102s1. Then, as illustrated in FIG. 1B, a plurality of communication devices 114 are mounted onto the first surface 102s1 of the substrate 102, in accordance with some embodiments. The communication devices 114 may be electrically coupled to the routing layers 110 of the substrate 102. The communication devices 114 may include a radio-frequency integrated circuit (RFIC), a power management IC (PMIC), another suitable device, or a combination thereof.

One or more electronic components 115 are mounted onto the first surface 102s1 of the substrate 102 and adjacent to the communication device 114, in accordance with some embodiments. The electronic components 115 may be electrically coupled to the routing layer 110 of the substrate 102. The electronic components 115 may include passive component, including resistor, inductor, capacitor, or a combination thereof.

A plurality of conductive connectors 116 may be formed over the first surface 102s1 of the substrate 102. The conductive connectors 116 may be adjacent to the communication devices 114 and the electronic components 115. The conductive connectors 116 may be electrically coupled to the routing layers 110 of the substrate 102. The conductive connectors 116 may include microbumps, controlled collapse chip connection (C4) bumps, conductive pillars, solder paste, ball grid array (BGA) balls, frame board, the like, or a combination thereof. The conductive connectors 116 may be formed of metal, including tungsten, titanium, tantalum, ruthenium, cobalt, copper, aluminum, platinum, tin, silver, gold, the like, an alloy thereof, or a combination thereof.

The communication device 114, the electronic components 115, and the conductive connectors 116 may be disposed over the same surface of the substrate 102, and may be arranged close to the module layer 108 and far from the antenna layer 106. The communication device 114, the electronic components 115, and the conductive connectors 116 may be arranged on the side of the substrate 102 which is opposite to the antenna layer 106.

Then, as illustrated in FIG. 1C, a molding material 118 is formed over the first surface 102s1 of the substrate 102 to encapsulate the communication device 114 and the electronic components 115, in accordance with some embodiments. The molding material 118 may protect these components from the environment, thereby protecting them from damage due to stress, chemicals, and moisture. The molding material 118 may be formed of a non-conductive material, including moldable polymer, epoxy, resin, the like, or a combination thereof.

The molding material 118 may partially cover the first surface 102s1 of the substrate 102 and may expose the conductive connectors 116, so that the antenna package structure may be electrically coupled to other electronic components, such as a printed circuit board (PCB) or any suitable component (not illustrated), through the conductive connectors 116.

Afterwards, a planarization process is performed on the molding material 118, in accordance with some embodiments. The planarization process may be performed until some of the top surfaces of the communication devices 114 and the electronic components 115 are exposed. The planarization process may include a chemical mechanical polishing (CMP) process, a mechanical grinding process, the like, or a combination thereof. As illustrated, the top surface of the molding material 118 may be substantially aligned with the top surface of some of the communication devices 114 and the electronic components 115.

Then, as illustrated in FIG. 1D, a first opening 120 is formed in the substrate 102, in accordance with some embodiments. The first opening 120 may be formed from the first surface 102s1 of the substrate 102. The first opening 120 may be formed by laser or another suitable methods. The first opening 120 may expose the sidewalls of the module layer 108 and the sidewalls of the protective layer 112 thereon, and may expose a portion of the sidewalls of the core structure 104.

According to some embodiments, the first opening 120 exposes the entire sidewall of the core structure 104 and exposes the top surface of the antenna layer 106. In these embodiments, the bottom surface of the first opening 120 is substantially aligned with the bottom surface of the core structure 104.

Then, as illustrated in FIG. 1E, the structure of FIG. 1D is disposed over a carrier structure 122, in accordance with some embodiment. The carrier structure 122 may include a carrier tape, a glass carrier substrate, a ceramic carrier substrate, another suitable structure, or a combination thereof.

Next, a shielding layer 124 is formed over the molding material 118 to cover the communication devices 114 and the electronic components 115, in accordance with some embodiments. The shielding layer 124 may extend over an upper portion of the sidewalls of the substrate 102 (including a portion of or the whole of the core structure 104, the module layer 108, and the protective layer 112) and the molding material 118. The shielding layer 124 may be formed by sputtering metal or any suitable material. The conductive connectors 116 may be masked by a lid or another suitable structure when forming the shielding layer 124. Then, the lid (not illustrated) may be removed after forming the shielding layer 124 to reveal the conductive connectors 116. As a result, a portion of the first surface 102s1 of the substrate 102 may be covered by the shielding layer 124 and another portion of the first surface 102s1 of the substrate 102 and the conductive connectors 116 may be exposed by the shielding layer 124.

The thickness of the shielding layer 124 may be in a range of about 1 μm to about 6 μm, such as about 4 μm. The thickness of the shielding layer 124 within this range can effectively block electromagnetic wave without increasing the volume of the antenna package structure.

The shielding layer 124 may be in contact with the first surface 102s1 of the substrate 102 and some of the top surfaces of the communication devices 114 and the electronic components 115 which are exposed by the molding material. In some embodiments where the first opening 120 exposes the top surface of the antenna layer 106, the shielding layer 124 extends to the top surface of the antenna layer 106. In these embodiments, the bottom surface of the shielding layer 124 may be substantially aligned with the bottom surface of the core structure 104.

Afterwards, as illustrated in FIG. 1F, the structure of FIG. 1E is disposed over a carrier structure 126 and the carrier structure 122 is removed, in accordance with some embodiments. The carrier structure 126 may be similar to the carrier structure 122, and will not be repeated.

Then, a second opening 128 is formed in the substrate 102, in accordance with some embodiments. The second opening 128 may be formed from the second surface 102s2 of the substrate 102. The formation of the second opening 128 and the first opening 120 may cut through the substrate 102 to singulate the structure of FIG. 1F and form the antenna package structures 100. The second opening 128 may be formed by laser or mechanic saw or another suitable methods. The second opening 128 may expose the sidewalls of the antenna layer 106 and the protective layer 112 thereon, and may expose a portion of the top surface of the core structure 104.

During the formation of the second opening 128, some of the shielding layer 124 may be removed. For example, a portion of the shielding layer 124 on the sidewall of the core structure 104 and on the surface of the antenna layer 106 may be removed. Therefore, the substrate 102 is partially coated. As a result, the antenna layer 106 would not be isolated from the inward and outward signals, and thus can radiate and receive electromagnetic wave well.

In some embodiments, the second opening 128 partially overlap the first opening 120, as illustrated. The depth D2 of the second opening 128 may be adjusted. For example, in some other embodiments, the sum of the depth D1 of the first opening 120 and the depth D2 of the second opening 128 is substantially equal to the thickness of the substrate 102.

According to some embodiments, the second opening 128 extends into the core structure 104. In particular, the depth D2 of the second opening 128 may be greater than the sum of the thicknesses T1 of the antenna layer 106 and the protective layer 112. The depth D2 of the second opening 128 may be greater than the thickness T2 of the antenna layer 106. The second opening 128 may expose the entire sidewall of the antenna layer 106 and may partially expose the top surface and the sidewall of the core structure 104.

The core structure 104 may have a stepped sidewall. In particular, the core structure 104 has an upper top surface in contact with the antenna layer 106 and a lower top surface which is exposed. The core structure 104 may have an upper sidewall exposed and a lower sidewall covered by the shielding layer 124.

According to some embodiments, the width W2 of the second opening 128 is greater than the width W1 of the first opening 120. This may make the sidewall of the module layer 108 and a portion of the sidewall of the core structure 104 protrude relative to the sidewall of the antenna layer 106 and another portion of the sidewall of the core structure 104. According to some other embodiments, the width W1 can be larger than the width W2.

The substrate 102 may include a first portion 102a and a second portion 102b with different widths. According to some embodiments, the first portion 102a of the substrate 102 includes the antenna layer 106 and a portion of the core structure 104, and the second portion 102b of the substrate 102 includes the module layer 108 and another portion of the core structure 104. The width W3 of the second portion 102b of the substrate 102 may be greater than the width W4 of the first portion 102a of the substrate 102. The sidewall of the second portion 102b of the substrate 102 may protrude relative to the sidewall of the first portion 102a of the substrate 102. According to some other embodiments, the width W4 can be larger than the width W3.

The distance D3 between the sidewall of the second portion 102b and the sidewall of the first portion 102a may be in a range of about 10 μm to about 90 μm, such as about 50 μm. When the distance D3 is within this range, the substrate 102 can be cut through without affecting the routing layers 110 in the antenna layer 106.

Then, as illustrated in FIG. 1G, the carrier structure 126 is removed and the antenna package structure 100 is flipped upside down, in accordance with some embodiments. The substrate 102 may have stepped sidewalls S1 on opposite sides. The stepped sidewalls S1 may each include the sidewall of the second portion 102b and the sidewall of the first portion 102a. In particular, each of the stepped sidewalls S1 may include the sidewall of the antenna layer 106 and the sidewall of a lower portion of the core structure 104, the upper bottom surface of the core structure 104, and the sidewall of the module layer 108 and the sidewall of another portion of the core structure 104.

The communication devices 114 and the electronic components 115 which are sensitive on electromagnetic wave may be surrounded by the shielding layer 124 to prevent inward and outward signal interference, and the antenna layer 106 may be exposed to radiate and receive electromagnetic wave.

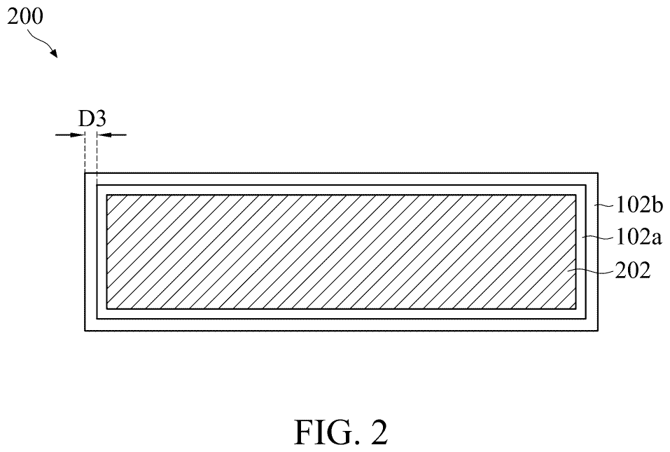

FIG. 2 is a bottom view of a substrate 200 of an antenna package structure in accordance with some embodiments of the present disclosure. It should be noted that the substrate 200 may include the same or similar components as those of the substrate 102 of the antenna package structure 100, which is illustrated in FIG. 1G, and for the sake of simplicity, those components will not be discussed in detail again.

As illustrated in FIG. 2, the substrate 200 may include the first portion 102a and the second portion 102b. The projection area of the second portion 102b of the substrate 102 may be greater than the projection area of the first portion 102a of the substrate 102. The projection area of the first portion 102a of the substrate 102 may be located within the projection area of the second portion 102b of the substrate 102.

The distance D3 between the sidewall of the first portion 102a of the substrate 102 and the sidewall of the second portion 102b of the substrate 102 may be the same or different on different sides. The design area 202 of the antenna may be located within the projection area of the first portion 102a of the substrate 102. Therefore, cutting through the substrate 102 would not damage the design area 202 of the antenna.

However, the present disclosure is not limited thereto. For example, both of the depth D1 of the first opening 120 and the depth D2 of the second opening 128 (as illustrated in FIG. 1F) may be adjusted to modify the thicknesses of the first portion 102a and the second portion 102b of the substrate 102, as discussed below.

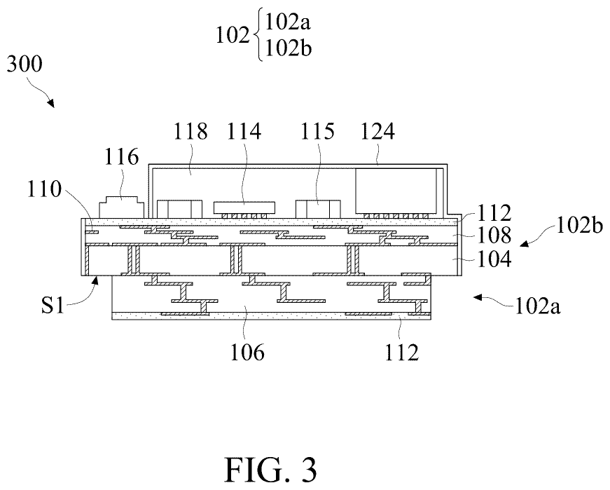

FIG. 3 is a cross-sectional view of an antenna package structure 300 in accordance with some embodiments of the present disclosure. It should be noted that the antenna package structure 300 may include the same or similar components as those of the antenna package structure 100, which is illustrated in FIG. 1G, and for the sake of simplicity, those components will not be discussed in detail again. In the following embodiments, the bottom surface of the second portion 102b of the substrate 102 is substantially aligned with the bottom surface of the core structure 104.

As illustrated in FIG. 3, the first portion 102a of the substrate 102 may include the antenna layer 106 and may not include the core structure 104. The second portion 102b of the substrate 102 may include the module layer 108 and may include the entire core structure 104. The core structure 104 may have a straight sidewall. The stepped sidewall S1 of the substrate 102 may include the sidewall of the antenna layer 106, the bottom surface and the sidewall of the core structure 104, and the sidewall of the module layer 108. The shielding layer 124 may extend to the bottom surface of the core structure 104. The bottommost surface of the shielding layer 124 may be substantially aligned with the bottom surface of the core structure 104.

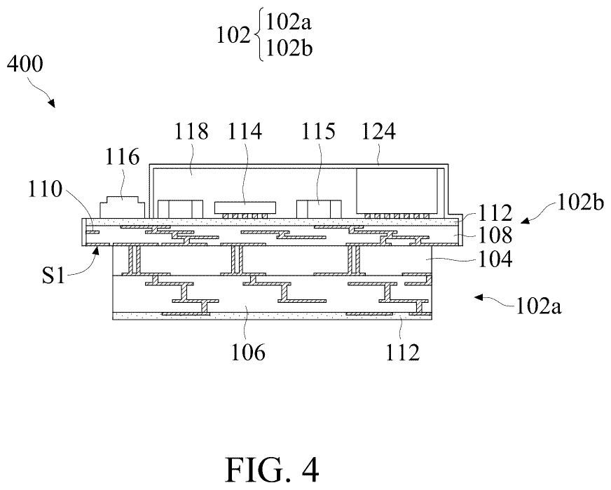

FIG. 4 is a cross-sectional view of an antenna package structure 400 in accordance with some embodiments of the present disclosure. It should be noted that the antenna package structure 400 may include the same or similar components as those of the antenna package structure 100, which is illustrated in FIG. 1G, and for the sake of simplicity, those components will not be discussed in detail again. In the following embodiments, the bottom surface of the second portion 102b of the substrate 102 is substantially aligned with the top surface of the core structure 104.

As illustrated in FIG. 4, the first portion 102a of the substrate 102 may include the antenna layer 106 and may include the entire core structure 104. The second portion 102b of the substrate 102 may include the module layer 108 and may not include the core structure 104. The core structure 104 may have a straight sidewall. The stepped sidewall S1 of the substrate 102 may include the sidewall of the antenna layer 106, the sidewall of the core structure 104, and the bottom surface and the sidewall of the module layer 108. The shielding layer 124 may extend to the bottom surface of the module layer 108 and may be separated from the core structure 104. The bottommost surface of the shielding layer 124 may be substantially aligned with the bottom surface of the module layer 108.

It should be understood that above embodiments can be combined to meet design requirements. For example, the thicknesses of the first portion 102a and the second portion 102b of the substrate 102 may be different on opposite sides.

As described previously, the antenna package substrate may include the shielding layer 124 which encapsulates the communication devices 114 to isolate the signal while exposing the antenna layer 106 to radiate and receive the signal. In the embodiments illustrated in FIG. 3, the shielding layer 124 further covers the entire sidewall of the core structure 104. In the embodiments illustrated in FIG. 4, the entire sidewall of the core structure 104 is exposed.

In summary, the antenna package structure according to the present disclosure includes an antenna layer and a communication device. By adopting the method for forming the antenna package structure according to the present disclosure, the communication device can be covered by a shielding layer while the antenna layer is exposed. As a result, the antenna can work well without adversely affecting the operation of the communication device.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An antenna package structure, comprising:
a substrate comprising:
an upper portion; and
a lower portion comprising an antenna layer,
wherein the substrate has stepped sidewalls on opposite sides, and each of the stepped sidewalls comprises a sidewall of the upper portion and a sidewall of the lower portion;
a communication device mounted onto the upper portion of the substrate; and
a shielding layer covering the communication device and the sidewall of the upper portion of the substrate.

2. The antenna package structure as claimed in claim 1, wherein the upper portion is wider than the lower portion of the substrate.

3. The antenna package structure as claimed in claim 1, further comprising:
a conductive connector disposed over the upper portion of the substrate and electrically coupled to the substrate,
wherein the shielding layer is separated from the conductive connector.

4. The antenna package structure as claimed in claim 1, wherein the upper portion of the substrate comprises a portion of a core structure and the lower portion of the substrate comprises another portion of the core structure, and a bottom surface of the shielding layer is substantially aligned with a bottom surface of the portion of the core structure.

5. The antenna package structure as claimed in claim 1, wherein the upper portion of the substrate comprises a core structure, and a bottom surface of the shielding layer is substantially aligned with a bottommost surface of the core structure.

6. The antenna package structure as claimed in claim 1, wherein the lower portion of the substrate comprises a core structure, and a bottom surface of the shielding layer is substantially aligned with a top surface of the core structure.

7. An antenna package structure, comprising:
a substrate comprising:
an antenna layer; and
a module layer disposed over the antenna layer,
wherein a sidewall of the module layer protrudes relative to a sidewall of the antenna layer;
a communication device disposed over the module layer of the substrate;
a molding material encapsulating the communication device;
a conductive connector adjacent to the molding material; and
a shielding layer extending on sidewalls of the molding material and the sidewall of the module layer.

8. The antenna package structure as claimed in claim 7, wherein the shielding layer extends on a top surface of the molding material and is in contact with a top surface of the substrate.

9. The antenna package structure as claimed in claim 7, further comprising:
a core structure disposed between the module layer and the antenna layer,
wherein a sidewall of the core structure protrudes relative to a sidewall of the antenna layer and is covered by the shielding layer.

10. The antenna package structure as claimed in claim 7, wherein a distance between the sidewall of the module layer and the sidewall of the antenna layer is in a range of about 10 μm to about 90 μm.

11. A method for forming an antenna package structure, comprising:
attaching a communication device to a first side of a substrate, wherein the substrate comprises an antenna layer on a second side of the substrate;
forming a first opening in the substrate;
forming a shielding layer over the communication device and in the first opening; and
forming a second opening in the substrate to the first opening to cut through the substrate.

12. The method for forming the antenna package structure as claimed in claim 11, wherein the shielding layer is partially removed when forming the second opening.

13. The method for forming the antenna package structure as claimed in claim 11, further comprising:
forming a molding material encapsulating the communication device, wherein the shielding layer is formed over the molding material.

14. The method for forming the antenna package structure as claimed in claim 13, further comprising:
planarizing the molding material to expose a top surface of the communication device, wherein the shielding layer is in contact with the communication device.

15. The method for forming the antenna package structure as claimed in claim 11, wherein the second opening is wider than the first opening.

16. The method for forming the antenna package structure as claimed in claim 11, wherein the first opening is formed from the first side of the substrate, and the second opening is formed from the second side of the substrate.

17. The method for forming the antenna package structure as claimed in claim 11, further comprising:
forming a conductive connector on the first side of the substrate;
masking the conductive connector during forming the shielding layer; and
revealing the conductive connector after forming the shielding layer.

18. The method for forming the antenna package structure as claimed in claim 11, wherein the substrate comprises a core structure, and the first opening exposes sidewalls of the core structure.

19. The method for forming the antenna package structure as claimed in claim 11, wherein the substrate comprises a core structure, and the second opening exposes a bottom surface of the core structure.

20. The method for forming the antenna package structure as claimed in claim 11, wherein a depth of the second opening is greater than a thickness of the antenna layer.
